(19) United States
(12) Patent Application Publication
(10) Pub. No.: US 2017/0271507 A1
(43) Pub. Date: Sep. 21, 2017

(54) SEMICONDUCTOR DEVICE

(71) Applicant: KABUSHIKI KAISHA TOSHIBA, Tokyo (JP)

(72) Inventors: Takuma SUZUKI, Himeji Hyogo (JP); Masaru FURUKAWA, Himeji Hyogo (JP); Hiroshi KONO, Himeji Hyogo (JP)

(21) Appl. No.: 15/243,835

(22) Filed: Aug. 22, 2016

(30) Foreign Application Priority Data
Mar. 16, 2016 (JP) 2016-053106

(51) Int. Cl. H01L 29/78; H01L 29/423; H01L 29/167; H01L 29/16

(52) U.S. Cl. CPC H01L 29/7827; H01L 29/1608; H01L 29/4236; H01L 29/167

(57) ABSTRACT

According to one embodiment, a semiconductor device includes a first electrode, a second electrode, a p-type first silicon carbide region between the first electrode and the second electrode, an n-type second silicon carbide region between the first electrode and the first silicon carbide region, a third silicon carbide region, containing an n-type impurity which is different from an n-type impurity in the second silicon carbide region, between the first electrode and the first silicon carbide region and an n-type fourth silicon carbide region between the first silicon carbide region and the second electrode. A third electrode is in the first silicon carbide region, the second silicon carbide region, and the fourth silicon carbide region and spaced therefrom by an insulating film.

### CROSS-REFERENCE TO RELATED APPLICATION

This application is based upon and claims the benefit of priority from Japanese Patent Application No. 2016-053106, filed Mar. 16, 2016, the entire contents of which are incorporated herein by reference.

### FIELD

Embodiments described herein relate generally to a semiconductor device.

### BACKGROUND

Silicon carbide (SiC) has attracted attention as a material for next generation semiconductor devices. As characteristics of SiC, the band gap size is about three times, the breakdown electric field strength is about ten times, and the thermal conductivity is about three times those of Silicon (Si). Therefore, by using SiC, it is possible to realize a semiconductor device which can operate at a high temperature with a low loss as compared to silicon based device.

In the semiconductor device using the SiC, there is a problem in the reliability of a gate insulating film.

### DESCRIPTION OF THE DRAWINGS

FIG. 1 is a schematic cross-sectional view of a semiconductor device in a first embodiment.

FIG. 2 is a flowchart of a method of manufacturing the semiconductor device in the first embodiment.

FIG. 3 is a schematic cross-sectional view of the semiconductor device during the manufacturing in the method of manufacturing the semiconductor device in the first embodiment.

FIG. 4 is a schematic cross-sectional view of the semiconductor device during the manufacturing in the method of manufacturing the semiconductor device in the first embodiment.

FIG. 5 is a schematic cross-sectional view of the semiconductor device during the manufacturing in the method of manufacturing the semiconductor device in the first embodiment.

FIG. 6 is a schematic cross-sectional view of the semiconductor device during the manufacturing in the method of manufacturing the semiconductor device in the first embodiment.

FIG. 7 is a schematic cross-sectional view of the semiconductor device during the manufacturing in the method of manufacturing the semiconductor device in the first embodiment.

FIG. 8 is a schematic cross-sectional view of the semiconductor device during the manufacturing in the method of manufacturing the semiconductor device in the first embodiment.

FIG. 9 is a Weibull plot of the semiconductor device including a silicon carbide region containing phosphorus in the first embodiment.

FIG. 10 is a Weibull plot of the semiconductor device including a silicon carbide region containing phosphorus in the first embodiment when a phosphorus concentration is approximately 1×10¹⁹ cm⁻³.

FIG. 11 is a Weibull plot of the semiconductor device including a silicon carbide region containing nitrogen.

FIG. 12 is a schematic cross-sectional view of a semiconductor device in a second embodiment.

FIG. 13 is a schematic cross-sectional view of a semiconductor device in a third embodiment.

### DETAILED DESCRIPTION

In general, according to one embodiment, a semiconductor device includes a first electrode, a second electrode, a p-type first silicon carbide region between the first electrode and the second electrode, an n-type second silicon carbide region between the first electrode and the first silicon carbide region, a third silicon carbide region, containing an n-type impurity which is different from an n-type impurity in the second silicon carbide region, between the first electrode and the first silicon carbide region, and an n-type fourth silicon carbide region between the first silicon carbide region and the second electrode. A third electrode is in the first silicon carbide region, the second silicon carbide region, and the fourth silicon carbide region and spaced therefrom by an insulating film.

Hereinafter, embodiments will be described using the drawings.

Herein, the same reference numbers will be given to the same or similar members, and in some cases where appropriate, the description thereof will not be repeated.

Herein, indications n⁺, n, n⁻, p⁺, p, and p⁻ represent the relative level of an impurity concentration in each conductivity type. That is, the n type impurity concentration of n⁺ is relatively higher than that of n, and then type impurity concentration of n⁻ is relatively lower than that of n. In addition, the p-type impurity concentration of p⁺ is relatively higher than that of p, and the p-type impurity concentration of p⁻ is relatively lower than that of p-type. In some cases, n⁺ and n⁻ are simply referred to as n-type, and p⁺ and p⁻ are simply referred to as p-type.

Herein, in order to illustrate position relationships, the upward direction in the drawings will be referred to as “upper” and the downward direction in the drawing will be referred to as “lower”. The concept of terms “upper” and “lower” herein is not necessarily indicating the relationship with the direction of gravity.

### First Embodiment

A semiconductor device 100 of the present embodiment includes a first electrode, a second electrode, a p-type first silicon carbide region provided between the first electrode and the second electrode, an n-type second silicon carbide region provided between the first electrode and the first silicon carbide region, a third silicon carbide region containing n-type impurity that is different from the n-type impurity contained in the second silicon carbide region provided between the first electrode and the first silicon carbide region, an n-type fourth silicon carbide region provided between the first silicon carbide region and the second electrode, and a third electrode provided in the first silicon carbide region, the second silicon carbide region and the fourth silicon carbide region via insulating films.

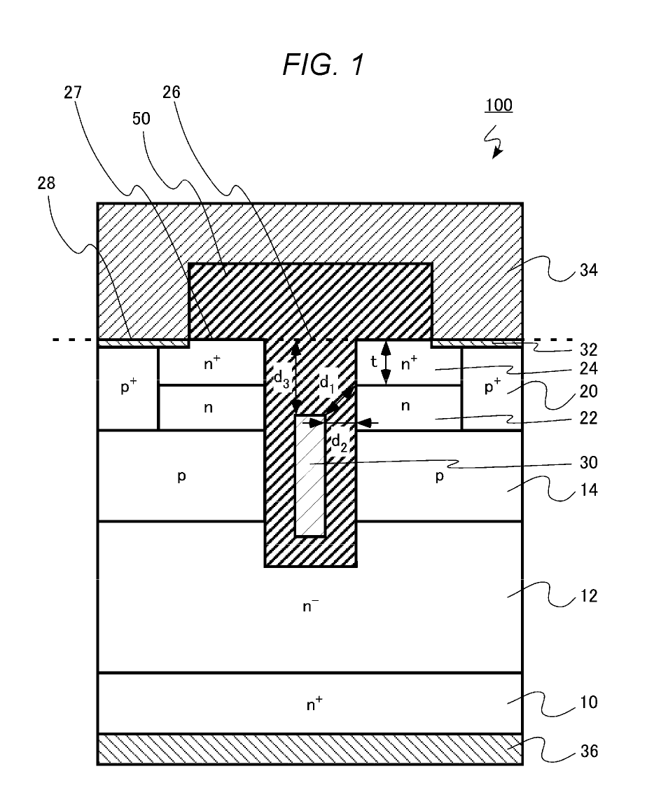

FIG. 1 is a schematic cross-sectional view of the semiconductor device 100 in the present embodiment. The semiconductor device 100 is a trench-type metal oxide semiconductor field effect transistor (MOSFET).

The semiconductor device 100 includes a first silicon carbide region 14, a second silicon carbide region 22, a third silicon carbide region 24, a fourth silicon carbide region 12, a fifth silicon carbide region 10, a sixth silicon carbide region 20, a first electrode 34, a second electrode 36, a third electrode 30, a fourth electrode 32, and an insulating film 50.

The first electrode 34 is a source electrode. The first electrode 34 is electrically connected to the fourth electrode 32. The first electrode 34 has a stacked structure of titanium (Ti) and aluminum (Al), and is formed by a known process such and physical vapor deposition. A barrier metal having a stacked structure of Ti, titanium nitride (TiN), and Al may be provided between the first electrode 34 and the fourth electrode 32. In addition, a passivation film (not illustrated) made from silicon nitride (SiN) may be provided on the upper portion of the first electrode 34.

The second electrode 36 is a drain electrode. The second electrode 36 is a metal silicide. Particularly, nickel silicide is preferably used for reducing contact resistance between the second electrode 36 and the fifth silicon carbide layer 10.

The first silicon carbide region 14 is provided between the first electrode 34 and the second electrode 36. The first silicon carbide region 14 is a well region. The first silicon carbide region 14 contains aluminum (Al) or boron (B) as the p-type impurity. Particularly, Al is preferable.

The second silicon carbide region 22 is provided between the first electrode 34 and the first silicon carbide region 14. Here, the third silicon carbide region 24 is provided between the first electrode 34 and the second silicon carbide region 22. The second silicon carbide region 22 contains nitrogen (N) as the n-type impurity.

The third silicon carbide region 24 is provided between the first electrode 34 and the first silicon carbide region 14, and in this embodiment, between the third silicon carbide region 22 and the first electrode 34. In addition, the third silicon carbide region 24 is a source region. The third silicon carbide region 24 contains an n-type impurity which is different from the n-type impurity contained in the second silicon carbide region 22, specifically, phosphorus (P) or arsenic (As). The third silicon carbide region 24 may further contain nitrogen (N) that is the n-type impurity contained in the second silicon carbide region 22.

The fourth silicon carbide region 12 is provided between the first silicon carbide region 14 and the second electrode 36. The fourth silicon carbide region 12 is a drift region. The fourth silicon carbide region 12 contains nitrogen, arsenic, phosphorus, or antimony (Sb) as the n-type impurity, for example, at a concentration equal to or higher than 1×10¹⁴ cm⁻³ and equal to or less than 3×10¹⁶ cm⁻³.

The fifth silicon carbide region 10 is provided between the fourth silicon carbide region 12 and the second electrode 36. The fifth silicon carbide region 10 is a drain region. The fifth silicon carbide region 10 contains nitrogen, arsenic, phosphorus, or antimony (Sb) as the n-type impurity, for example, at a concentration equal to or higher than 1×10¹⁸ cm⁻³ and equal to or less than 1×10²⁰ cm⁻³.

The insulating film 50 contacts the first silicon carbide region 14, the second silicon carbide region 22, and the fourth silicon carbide region 12. In addition, the insulating film contacts the third silicon carbide region 22. The insulating film 50 is a gate insulating film. The insulating film 50 is, for example, a silicon oxide film or a high-k film.

The third electrode 30 is located within the first silicon carbide region 14, the second silicon carbide region 22, and the fourth silicon carbide region 12 and insulated therefrom by the insulating film 50. In addition, the third electrode 30 is insulated from the third silicon carbide region 24 by the insulating film 50. The third electrode 30 is a gate electrode. The third electrode 30 is, for example, an impurity doped polycrystalline silicon.

The sixth silicon carbide region 20 is provided between the first electrode 34 and the first silicon carbide region 14, and at the sides of the third silicon carbide region 24 and the second silicon carbide region 22. The sixth silicon carbide region 20 is a contact region. The sixth silicon carbide region 20 is used to reduce electrical resistance between a fourth electrode 32 and the first silicon carbide region 14. The sixth silicon carbide region 20 contains Al, boron (B), or gallium (Ga) as the p-type impurity, for example, at a concentration equal to or higher than 1×10¹⁹ cm⁻³ and equal to or less than 1×10²⁰ cm⁻³.

The fourth electrode 32 is provided between the third silicon carbide region 24, the sixth silicon carbide region 20 and the first electrode 34. The fourth electrode 32 is a contact electrode. The fourth electrode 32 is a metal silicide (compound of metal and silicon). Examples of the metal silicide include titanium silicide, aluminum silicide, nickel silicide, cobalt silicide, tantalum silicide, tungsten silicide and hafnium silicides. Nickel silicide is preferable as the metal silicide described above for reducing the contact resistance between the fourth electrode and the third and sixth silicon carbide regions.

The distance d₃ between a plane 26 including the upper surface of the third silicon carbide region and the third electrode 30 is greater than the thickness t of the third silicon carbide region 24. The impurity concentration of the second silicon carbide region 22, the boundary of which with the first silicon carbide region 14 is farther from plane 26 than the distance d₃ between the plane 26 including the upper surface of the third silicon carbide region and the third electrode 30, is lower than the impurity concentration of the third silicon carbide region 24. The impurity concentration of the second silicon carbide region 22 is equal to or less than 1×10¹⁹ cm⁻³, and the impurity concentration of the third silicon carbide region 24 is equal to or higher than 1×10¹⁹ cm⁻³. The distance d₁ between the third electrode 30 and the third silicon carbide region 24 is equal to or more than twice a distance d₂ between the third electrode 30 and the second silicon carbide region 22.

The impurity concentrations, widths, shapes, and film thicknesses of the silicon carbide regions in the present embodiment can be measured using analysis methods such as scanning probe microscope (SPM), scanning spreading resistance microscopy (SSRM), secondary ion mass spectrometry (SIMS), scanning capacitance microscopy (SCM), transmission electron microscope (TEM)—energy dispersive X-ray spectroscopy (EDX), electron energy-loss spectroscopy (TEM-EELS), or the combination of above described analysis methods.

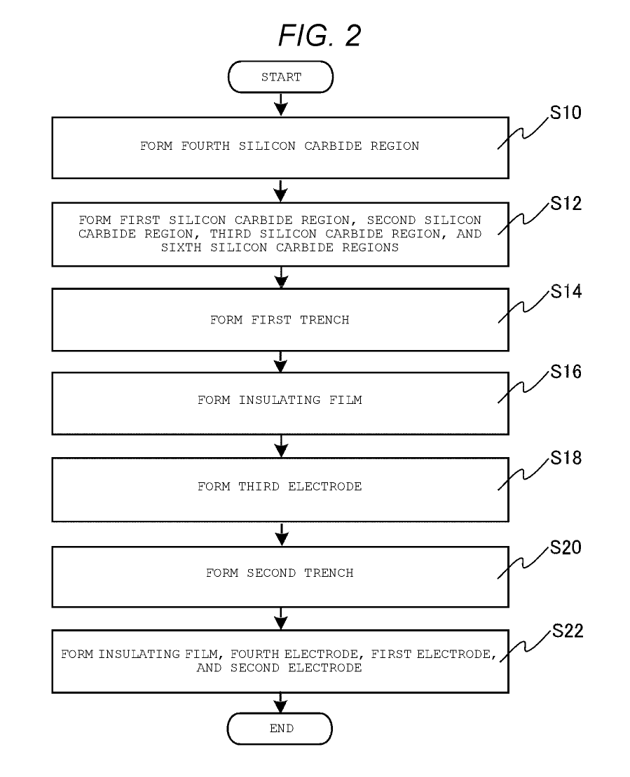

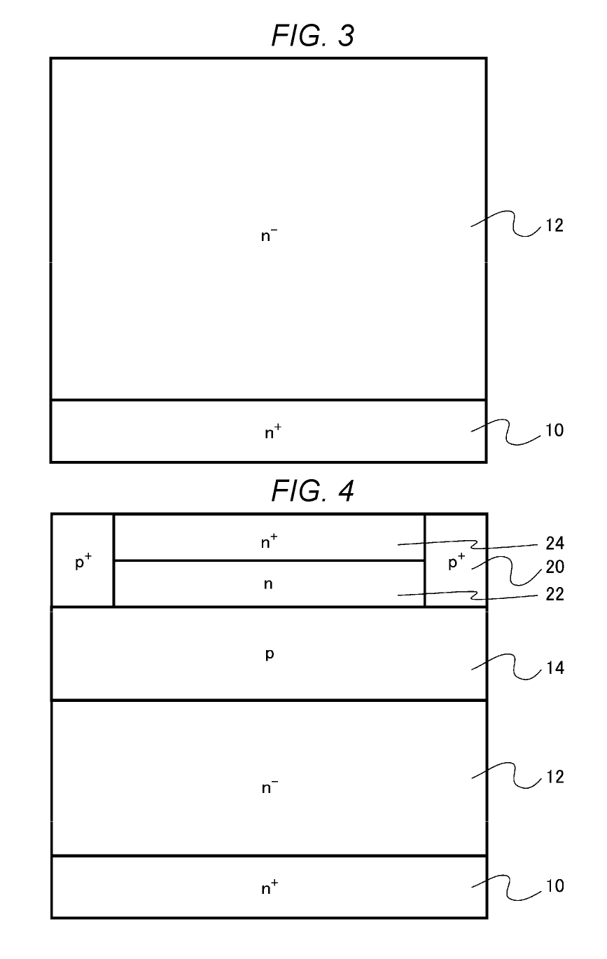

Next, a method of manufacturing the semiconductor device 100 in the present embodiment will be described. FIG. 2 is a flowchart of a method of manufacturing the semiconductor device 100 in the present embodiment. FIG. 3 to FIG. 8 are schematic cross-sectional views of the semiconductor device during the manufacturing in the method of manufacturing the semiconductor device in the first embodiment.

The method of manufacturing the semiconductor device 100 in the present embodiment includes forming the n-type fourth silicon carbide region 12 on the n⁺-type fifth silicon carbide region 10, forming the p-type first silicon carbide region 14 on the fourth silicon carbide region 12, forming the n-type second silicon carbide region 22 on the first silicon carbide region 14, forming the n-type third silicon carbide region 24 on the second silicon carbide region 22, forming the p-type sixth silicon carbide regions 20 at the sides of the third silicon carbide region 24 and the second silicon carbide region 22 on the first silicon carbide region 14, forming a first trench 40 passing through the third silicon carbide region 24, the second silicon carbide region 22, and the first silicon carbide region 14 and having a bottom portion 42 on the fourth silicon carbide region 12, forming the insulating film 50 in the first trench 40, forming the third electrode 30 on the insulating film 50 in the first trench 40, forming a second trench 44 while removing a part of the third electrode 30, forming the insulating film 50 on the second trench 44 and the third silicon carbide region 24, forming the fourth electrode 32 on the third silicon carbide region 24 and the sixth silicon carbide region 20, forming the first electrode 34 on the fourth electrode 32 and the insulating film 50, and forming the second electrode 36 on the fifth silicon carbide region 10 on the side opposite to the fourth silicon carbide region 12.

First, as illustrated in FIG. 3, the n-type fourth silicon carbide region 12 is formed on the n⁺-type fifth silicon carbide region 10 using, for example, an epitaxial growth method (S10).

Next, the p-type first silicon carbide region 14 is formed on the fourth silicon carbide region 12 using, for example, an Al ion implantation method. Next, the second silicon carbide region 22 is formed on the first silicon carbide region 14 using, for example, ion implantation of Nitrogen. Next, the third silicon carbide region 24 is formed on the second silicon carbide region 22 using, for example, ion implantation of P or As. Next, the sixth silicon carbide regions 20 are formed at the sides of the third silicon carbide region 24 and the second silicon carbide region 22 on the first silicon carbide region 14 using, for example, ion implantation of Al or B (S12). The structure at this stage is illustrated in FIG. 4. Next, a heat treatment is performed for activating impurities in the first silicon carbide region 14, the third silicon carbide region 24, and the sixth silicon carbide region 20.

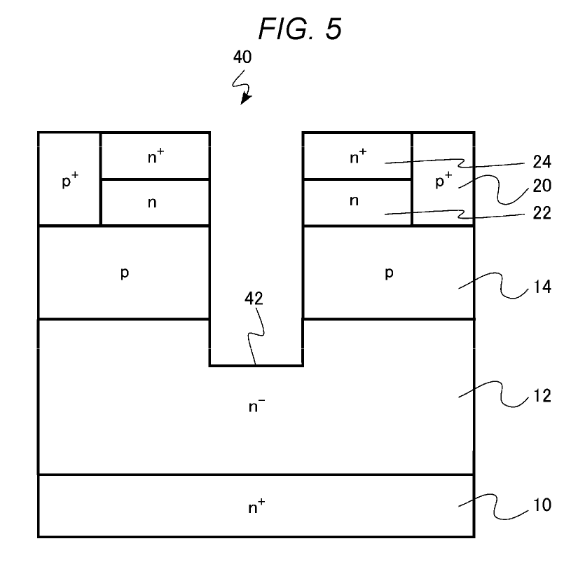

Next, as illustrated in FIG. 5, a first trench 40 is formed passing through the third silicon carbide region 24, the second silicon carbide region 22, and the first silicon carbide region 14 and terminating in a bottom portion 42 in the fourth silicon carbide region 12 using, for example, reactive ion etching method (RIE) (S14).

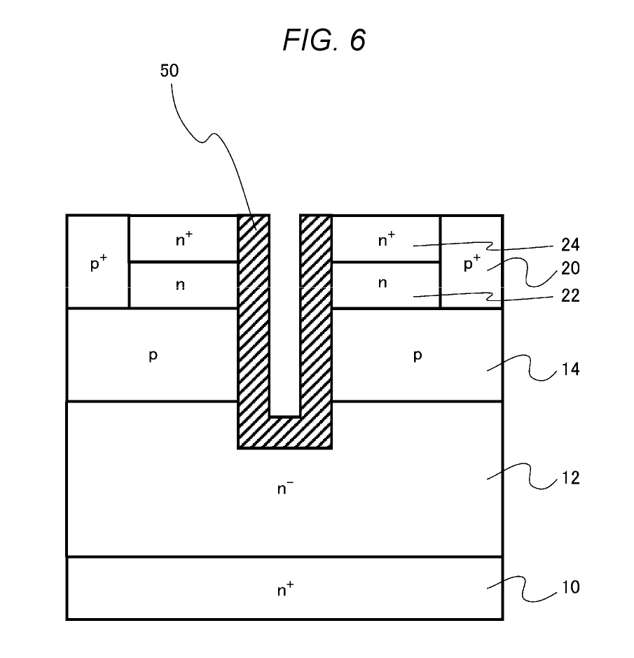

Next, as illustrated in FIG. 6, a silicon dioxide insulating film 50 is formed in the first trench 40 using, for example, a chemical vapor deposition (CVD) method (S16).

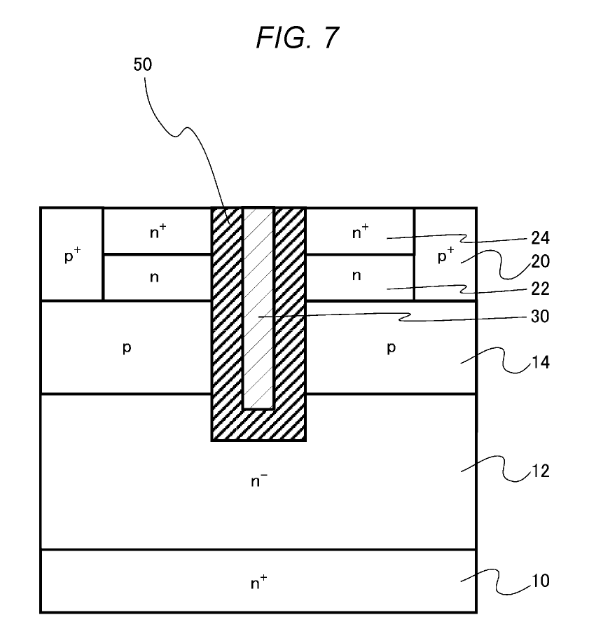

Next, as illustrated in FIG. 7, the third electrode 30 containing impurity doped polycrystalline silicon is formed on the insulating film 50 using, for example, the CVD method (S18).

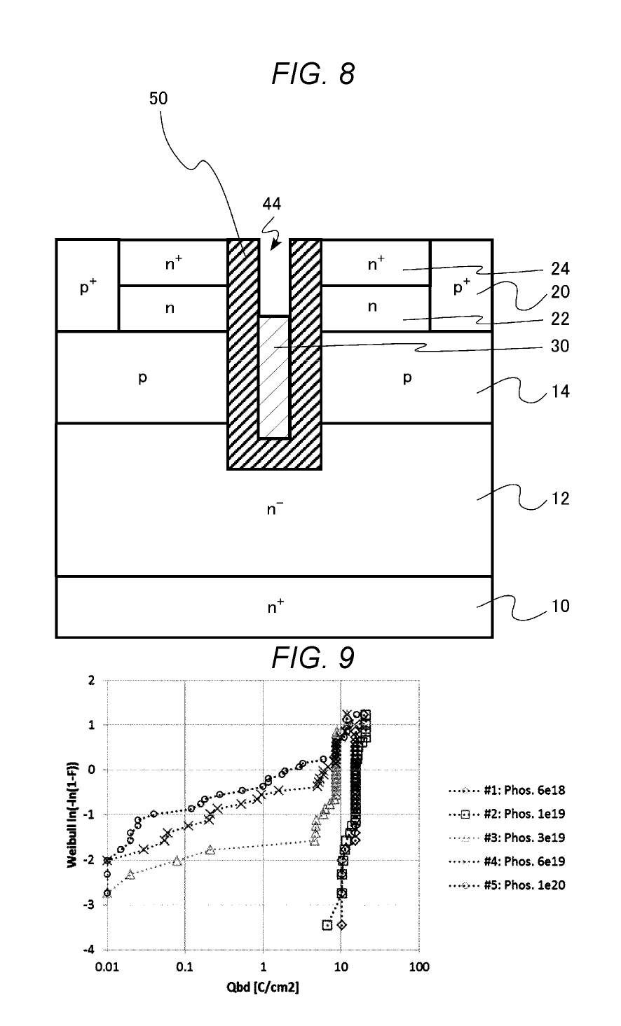

Next, as illustrated in FIG. 8, a second trench 44 is formed by removing a portion of the third electrode 30 using the RIE method, followed by polishing the surfaces of the insulating film 50, the third silicon carbide region 24, and the sixth silicon carbide region 20 using a chemical mechanical polishing (CMP) method (S20).

Next, the semiconductor device 100 is obtained by: forming the insulating film 50 in the second trench 44 and on the third silicon carbide region 24; forming the fourth electrode 32 on the third silicon carbide region 24 and the sixth silicon carbide region 20; forming the first electrode 34 on the fourth electrode 32 and the insulating film 50; and forming the second electrode 36 on the fifth silicon carbide region 10 on the side opposite to the fourth silicon carbide region 12, using known processes (S22).

Next, operational effects of the semiconductor device 100 in the present embodiment will be described.

In the gate insulating film provided on the surface of the region in which the impurities are implanted using the ion implantation method, the greater an amount of ion implantation becomes, the shorter the life time of the gate insulating film becomes.

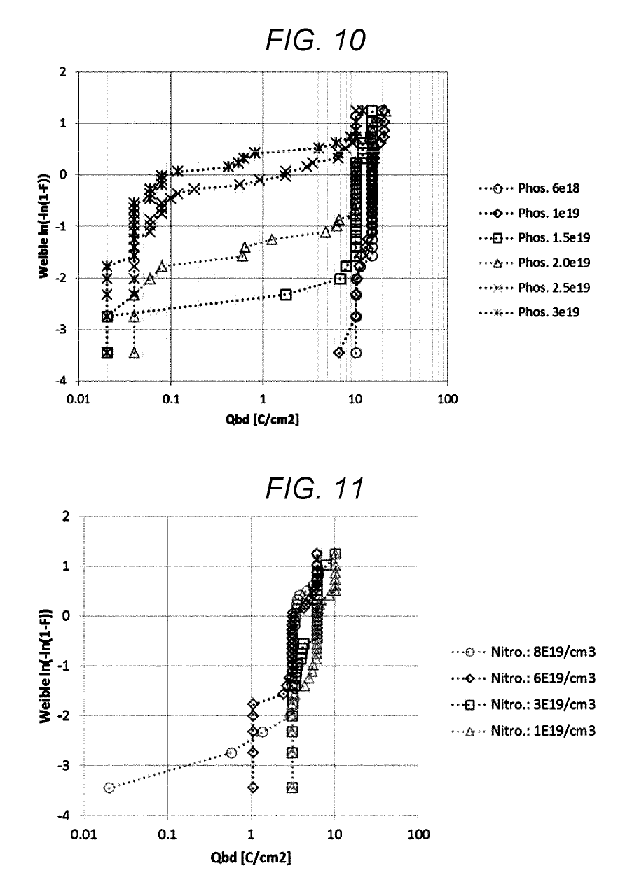

FIG. 9 is a Weibull plot of the semiconductor device 100 using phosphorus as the n-type impurity, which depicts implanted charge to breakdown amounts (Qbd) of the gate insulating film on the horizontal axis and cumulative failure rates on the vertical axis. FIG. 10 is a Weibull plot of the semiconductor device 100 in which the phosphorus concentration ranges between approximately 6×10¹⁸ cm⁻³ to 2×10²⁰ cm⁻³. When the phosphorus concentration is in the lower part of the range, the gate insulating film breakdown dominantly occurs at approximately 10 C/cm² of charge to breakdown amount (Qbd), and the slope of the Weibull plot is steep, that is, the slope is greater than 1. This charge to breakdown amount indicates the charge to breakdown amount that the insulating film originally has, and this state is a breakdown mode called an intrinsic failure mode (or a C mode failure). On the other hand, as the phosphorus concentration increases by virtue of adding additional impurities, the occurrence of a breakdown mode called an initial failure mode (or an A mode failure) in which a much smaller charge to breakdown amount (Qbd) than the charge to breakdown amount of the C mode leads to the breakdown, and a failure mode called an accidental failure mode (or a B mode failure) in which the charge to breakdown amount in the middle of the C mode and the A mode accidentally leads to the breakdown, increases. The threshold value of phosphorus concentration for causing the B mode failure is 1×10¹⁹ cm⁻³ as illustrated in FIG. 9 and FIG. 10, and there is no A mode failure or B mode failure when the phosphorus concentration is lower than above value.

In FIG. 11, a Weibull plot of the semiconductor device 100 using nitrogen as the n-type impurity is illustrated. It can be understood that the A mode failure and the B mode failure do not occur unless the impurity concentration reaches 6×10¹⁹ cm⁻³ which is a higher concentration than the concentration in the case of using phosphorus.

As described above, it is preferable that the impurity concentration is low for preventing the insulation breakdown, and on the other hand, it is preferable that the impurity concentration in the vicinity of the electrode is high for reducing the contact resistance of the silicon carbide layers and the electrodes.

The semiconductor device 100 in the present embodiment includes the third silicon carbide region 24 containing phosphorus or arsenic, and the second silicon carbide region 22 containing nitrogen. For phosphorus or arsenic, the solid solubility and activity in silicon carbide are high. Therefore, by providing the third silicon carbide region 24 described above, the contact resistance to the fourth electrode can be reduced and the electrical resistance of the semiconductor device 100 can be reduced. In addition, as illustrated in FIG. 11, in the case of using nitrogen as the impurity, since the B mode failure occurs at the lower impurity concentration compared to the case of using the phosphorus, it can be said that the damage on the silicon carbide regions due to the ion implantation is smaller than that in a case of using the phosphorus. Therefore, since the silicon carbide regions having a smaller incidence of failure can be disposed, of which the damage due to the ion implantation is small in the vicinity of the third electrode 30 or the insulating film 50, it is possible to provide a highly reliable semiconductor device 100.

Since the solid solubility and activity of the phosphorus to the silicon carbide is particularly higher than that of the arsenic, it is preferable that the third silicon carbide region 24 contains the phosphorus.

Since the third silicon carbide region 24 can be provided appropriately separated from the third electrode 30 by making the distance d₃ between the plane 26 including the upper surface of the third silicon carbide region and the third electrode 30 longer than the film thickness t of the third silicon carbide region, it is possible to provide further highly reliable semiconductor device 100.

Since the impurity concentration of the second silicon carbide region 22 adjacent to the third electrode 30 can be reduced by making the impurity concentration of the second silicon carbide region 22 lower than the impurity concentration of the third silicon carbide region 24, similarly, it is possible to provide the highly reliable semiconductor device 100.

The impurity concentration of the second silicon carbide region 22, the boundary of which with the first silicon carbide region 14 is farther from plane 26 than the distance d₃ between the plane 26 including the upper surface of the third silicon carbide region and the third electrode 30, is equal to or lower than 1×10¹⁹ cm⁻³, and the impurity concentration of the third silicon carbide region 24 is equal to or higher than 1×10¹⁹ cm⁻³. Therefore, the impurity concentration of the second silicon carbide region 22 adjacent to the third electrode 30 can be reduced, and thus, it is possible to provide the highly reliable semiconductor device 100.

The distance d₁ between the third electrode 30 and the third silicon carbide region 24 is equal to or more than twice the distance d₂ between the third electrode and the second silicon carbide region 22. Therefore, the third silicon carbide region 24 can be provided appropriately separated from the third electrode 30, and thus, it is possible to provide the highly reliable semiconductor device 100.

In a case of boron (B), it is not so easy to control the desired impurity concentration profile since the boron diffuses into the silicon carbide regions at the time of the activation heat treatment. In addition, since gallium (Ga) is unstable element, Ga is not suitable for a stable handling as ion implantation species. Aluminum (Al) has no problem as described above, and is preferable as the p-type impurity. Accordingly, it is preferable that the first silicon carbide region 14 contains Al.

As described above, according to the semiconductor device in the present embodiment, it is possible to provide the highly reliable semiconductor device.

### Second Embodiment

A semiconductor device 200 of this embodiment is different from the semiconductor device of the first embodiment in that the second silicon carbide region 22 is provided between the insulating film 50 and the third silicon carbide region 24, and between the first silicon carbide region 14 and the third silicon carbide region 24. Here, a description that overlaps with that of the first embodiment will not be described.

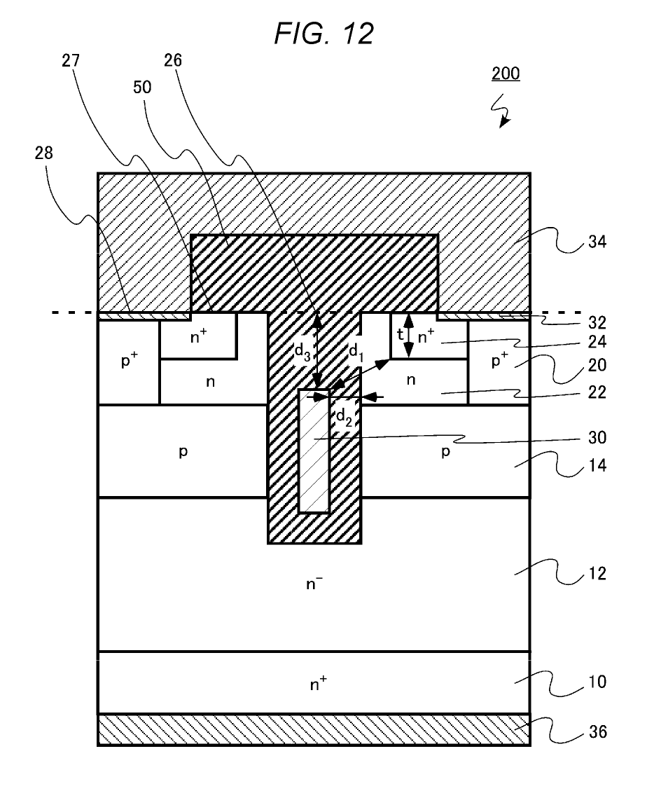

FIG. 12 is a schematic cross-sectional view of the semiconductor device 200 of the second embodiment.

In the semiconductor device 200 in the present embodiment, direct contact between the third silicon carbide region 24 and the insulating film 50 is reduced. Therefore, it is possible to provide the further highly reliable semiconductor device.

### Third Embodiment

A semiconductor device 300 of this embodiment is different from the semiconductor device of the first embodiment in that the second silicon carbide region 22 is provided between the insulating film 50 and the third silicon carbide region 24. Here, a description that overlaps with that of the first embodiment and the second embodiment is not provided.

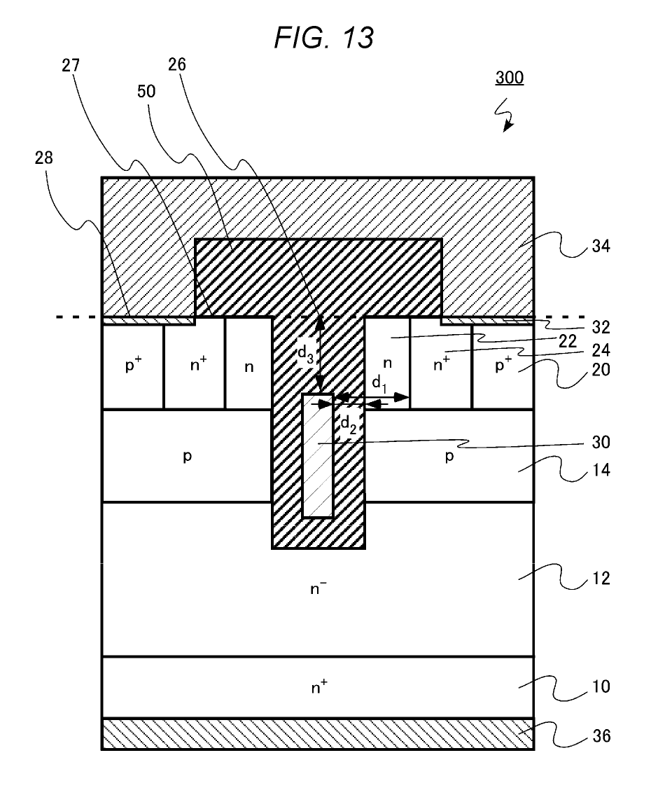

FIG. 13 is a schematic cross-sectional view of a semiconductor device 300 of the third embodiment.

In the semiconductor device 300 of this embodiment, the impurity concentration of the second silicon carbide region 22, the boundary of which with the first silicon carbide region 14 is farther from plane 26 than the distance d₃ between the plane 26 including the upper surface of the third silicon carbide region and the third electrode 30, is lower than the impurity concentration of the third silicon carbide region 24. The impurity concentration of the second silicon carbide region 22 is equal to lower than 1×10¹⁹ cm⁻³ and the impurity concentration of the third silicon carbide region 24 is equal to or higher than 1×10¹⁹ cm⁻³. The distance d₁ between the third electrode 30 and the third silicon carbide region 24 is equal to or more than twice the distance d₂ between the third electrode 30 and the second silicon carbide region 22.

In the semiconductor device 300 in the present embodiment, the insulating film 50 and the third silicon carbide region 24 are not in direct contact with each other. Therefore, in the semiconductor device 300 in the present embodiment as well, direct contact between the third silicon carbide region 24 and the insulating film 50 is reduced. Therefore, it is possible to provide the further highly reliable semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor device, comprising:
a first electrode;
a second electrode;
a p-type first silicon carbide region between the first electrode and the second electrode;
an n-type second silicon carbide region located between the first electrode and the first silicon carbide region;
a third silicon carbide region, containing an n-type impurity which is different from an n-type impurity in the second silicon carbide region, located between the first electrode and the first silicon carbide region;
an n-type fourth silicon carbide region located between the first silicon carbide region and the second electrode; and
a third electrode in the first silicon carbide region, the second silicon carbide region, and the fourth silicon carbide region and spaced therefrom by an insulating film.

2. The semiconductor device according to claim 1,
wherein the n-type impurity contained in the second silicon carbide region is nitrogen.

3. The semiconductor device according to claim 1,
wherein the n-type impurity contained in the third silicon carbide region is phosphorus.

4. The semiconductor device according to claim 1,
wherein the third silicon carbide region is between the first electrode and the second silicon carbide region.

5. The semiconductor device according to claim 1,
wherein the second silicon carbide region is located between the insulating film and the third silicon carbide region, and between the first silicon carbide region and the third silicon carbide region.

6. The semiconductor device according to claim 1,
wherein the distance between a plane, including the upper surface of the third silicon carbide region, and the third electrode is greater than the film thickness of the third silicon carbide region.

7. The semiconductor device according to claim 1,
wherein the impurity concentration of the second silicon carbide region is lower than the impurity concentration of the third silicon carbide region.

8. The semiconductor device according to claim 1,
wherein the impurity concentration of the second silicon carbide region is less than or equal to 1×10¹⁹ cm⁻³, and the impurity concentration of the third silicon carbide region is greater than or equal to 1×10¹⁹ cm⁻³.

9. The semiconductor device according to claim 1,
wherein the distance between the third electrode and the third silicon carbide region is equal to or greater than twice the distance between the third electrode and the second silicon carbide region.

10. The semiconductor device according to claim 1,
wherein the first silicon carbide region comprises aluminum.

11. A semiconductor device, comprising:
a first electrode;
a second electrode;
a silicon carbide layer between the first electrode and the second electrode, the silicon carbide layer comprising:
a first conductivity type first region overlying the first electrode;
a second conductivity type second region interposed between the first region and the second electrode;
a first conductivity type third region interposed between the second region and the second electrode;
a first conductivity type fourth region interposed between the second region and the second electrode; and
a second conductivity type fifth region interposed between the second region and the second electrode, wherein the first conductivity type impurities in the third region are different than the first conductivity type impurities in the fourth region;
a trench extending inwardly of the silicon carbide layer from the second electrode, a third electrode in the trench; and
a silicide region interposed between the second electrode and the fifth region.

12. The semiconductor device according to claim 11, wherein the silicide region is interposed between a portion of the fourth region and the electrode.

13. The semiconductor device according to claim 11, wherein the fourth region is interposed between the third region and the second electrode.

14. The semiconductor device according to claim 11, wherein the concentration of a first type impurity in the fourth region is greater than the concentration of a first type impurity in the third region.

15. The semiconductor device according to claim 11, further comprising an insulating layer extending between the third electrode and the first region, the second region, and the third region.

16. A semiconductor device, comprising:
a first electrode;
a second electrode;
a silicon carbide layer between the first electrode and the second electrode, the silicon carbide layer comprising:
a first conductivity type first region overlying the first electrode;
a second conductivity type second region interposed between the first region and the second electrode;
a first conductivity type third region interposed between the second region and the second electrode; and
a first conductivity type fourth region interposed between the second region and the second electrode, wherein the first conductivity type impurities in the third region are different than the first conductivity type impurities in the fourth region;
a trench extending inwardly of the silicon carbide region from the second electrode, a third electrode located in the trench; and
an insulating layer interposed between the second electrode and the third electrode, between the third electrode and the second and third regions and at least one of the third and fourth regions, and between the second electrode and at least one of the third and fourth regions.

17. The semiconductor device according to claim 16, wherein the uppermost extension of the third electrode is located inwardly of the silicon carbide layer a shorter distance than the thickness of the third region.

18. The semiconductor device according to claim 16, wherein the uppermost extension of the third electrode is located inwardly of the silicon carbide layer a shorter distance than the sum of the thicknesses of the third and fourth regions.

19. The semiconductor device according to claim 16, further comprising a silicide layer interposed between a portion of the fourth region and the second electrode.
